(19) United States
(12) Patent Application Publication
(10) Pub. No.: US 2005/0036635 A1
(43) Pub. Date: Feb. 17, 2005

(54) Audio signal output device

(75) Inventor: Ryosuke Inagaki, Kyoto (JP)

Correspondence Address: ARENT FOX PLLC, Suite 400, 1050 Connecticut Avenue, N.W., Washington, DC, 20036-5339, US

(73) Assignee: ROHM CO., LTD.

(21) Appl. No.: 10/914,277

(22) Filed: Aug. 10, 2004

(30) Foreign Application Priority Data
Aug. 12, 2003 (JP) 2003-291891

(51) Int. Cl. H03F 21/00

(52) U.S. Cl. 381/120

(57) ABSTRACT

An audio signal output device that suppresses the effect of noise from the digital IC via the power supply and that permits reduced costs is provided. The audio signal output device comprises a regulator capable of a stabilized supply of power regardless of the noise from the digital IC. The first input stage amplifier, to which an audio signal is inputted and the second input stage amplifier, which inverts the output of the first output stage amplifier, employ the output of the regulator as a power supply source, while the first and second output stage amplifiers, which drive the speaker and consume a large amount of electrical power, employ the power supply voltage (Vdd) directly as a power supply source.

### BACKGROUND OF THE INVENTION

1. Field of the Invention

The present invention relates to an audio signal output device constituted by an analog IC.

2. Description of the Related Art

Conventionally, in devices for processing audio signal such as cellular phones, personal computers, PDA, and PDC, an analog IC such as an audio signal output device, and digital IC such as a DSP (Digital Signal Processor), a CODEC (Coder-decoder), and a DA converter (Digital-to-analog converter) are disposed on a single substrate, and the power supply for the analog IC and digital IC are normally shared. In this case, noise from the digital IC wraps around the analog IC via the power supply to cause degradation of the analog IC characteristics.

For this reason, the practice of separating the digital IC power supply and analog IC power supply to inhibit noise from the digital IC from wrapping around the analog IC exists (Japanese Patent Application Laid Open No. H7-104340, for example). More specifically, the power supply constitution is such that power is supplied from the power supply voltage to the digital IC, and a regulator IC, which outputs a predetermined voltage that is lower than the power supply voltage, is interposed between the power supply voltage and the analog IC so that power is supplied from the regulator IC to the analog IC.

FIG. 3 is a circuit diagram of an audio signal output device that uses this approach for the power supply constitution. An audio signal output device 101 comprises an input stage amplifier 102 that produces an output by inverting and amplifying an audio signal inputted thereto, an output stage amplifier 103 that produces an output by current-amplifying the output of the input stage amplifier 102 inputted thereto to drive one terminal of the drive input of a speaker 106; an input stage amplifier 104 that produces an output by inverting the output of the output stage amplifier 103 inputted thereto; and an output stage amplifier 105 that produces an output by current-amplifying the output of the input stage amplifier 104 inputted thereto to drive the other terminal of the drive input of the speaker 106. This audio signal output part, which comprises these amplifiers 102, 103, 104, and 105, constitutes an analog IC. In addition, in the audio signal output device 101, a regulator IC 110, which outputs a predetermined voltage that is lower than the power supply voltage (Vdd), is interposed between the power supply voltage (Vdd) and analog IC. This regulator IC 110 thus constitutes the source of power for the amplifiers 102, 103, 104, and 105. Accordingly, the regulator IC 110 suppresses the noise from the digital IC (not shown) that wraps around the analog IC (amplifiers 102, 103, 104, and 105) via the power supply voltage (Vdd).

### SUMMARY OF THE INVENTION

As a result of the power supply constitution, the noise from the digital IC that wraps around the analog IC via the power supply voltage (Vdd) can be suppressed. However, the audio signal output device normally drives speakers, headphones, and so forth with a low impedance of about 4 to 16 Ω. Therefore, the regulator IC requires a current capacity of 2 to 3 A or more. Heat generation cannot be disregarded with a regulator IC of this current capacity, and hence a heat sink is generally provided. The surface area occupied by the regulator IC on the substrate increase as a result, then there are problems such as increased costs.

The present invention was conceived on these grounds, an object thereof being to provide an audio signal output device that suppresses the effect of noise from the digital IC via the power supply and that permits reduced costs.

In order to solve the above problems, the audio signal output device according to the present invention comprises a first input stage amplifier that produces an output by inverting and amplifying an audio signal inputted thereto; a first output stage amplifier that produces an output by current-amplifying the output signal of the first input stage amplifier inputted thereto to drive one terminal of the drive input of a speaker; a second input stage amplifier that produces an output by inverting the output signal of the first output stage amplifier inputted thereto; a second output stage amplifier that produces an output by current-amplifying the output signal of the second input stage amplifier inputted thereto to drive the other terminal of the drive input of the speaker; and a regulator that is connected to the power supply voltage and outputs a predetermined constant voltage that is lower than the power supply voltage, wherein the first and second input stage amplifiers employ the regulator as a power supply source and the first and second output stage amplifiers employ the power supply voltage as the power supply source.

In the audio signal output device according to the present invention, the first and second input stage amplifiers employ a regulator as a power supply source and the first and second output stage amplifiers employ a power supply voltage as a power supply source. Therefore, even though the digital IC generates noise, the first and second input stage amplifiers are not subjected to the effects of noise from the regulator, and, because the regulator is not the power supply source of the first and second output stage amplifiers with a high power consumption, the heat generation is small and the conventionally required heat sink is no longer necessary. Therefore, the occupied area on the substrate is small and the effect of noise from the digital IC via the power supply can be suppressed and costs can be reduced.

### BRIEF DESCRIPTION OF THE DRAWINGS

FIG. 1 is a circuit diagram of the audio signal output device of the embodiment of the present invention;

FIG. 2 is a circuit diagram showing the detailed constitution of the audio signal output device; and

FIG. 3 is a circuit diagram of the audio signal output device of the prior art.

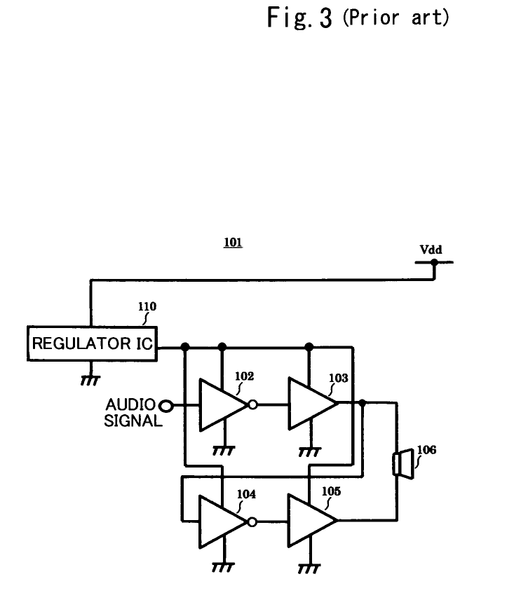

### DETAILED DESCRIPTION OF THE PREFERRED EMBODIMENT

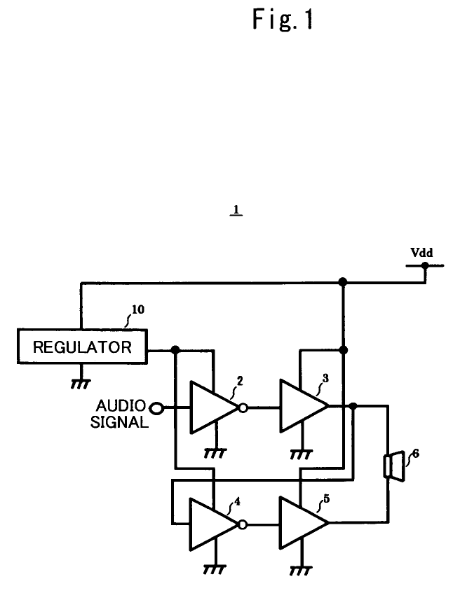

The audio signal output device constituting the embodiment of the present invention is described based on FIG. 1. The audio signal output device 1 comprises an input stage amplifier (first input stage amplifier) 2 that produces an output by inverting and amplifying an audio signal inputted thereto; an output stage amplifier (first output stage amplifier) 3 that produces an output by current-amplifying the output of the input stage amplifier 2 inputted thereto to drive one terminal of the drive input of a speaker (including headphones) 6; an input stage amplifier (second input stage amplifier) 4 that produces an output by inverting the output signal inputted thereto; and an output stage amplifier (second output stage amplifier) 5 that produces an output by current-amplifying the output of the input stage amplifier 4 inputted thereto to drive the other terminal of the drive input of the speaker 6. Therefore, a so-called BTL (Balanced Transformerless) constitution, in which both terminals of the drive input of the speaker 6 are driven with mutually opposite phases, is produced. The audio signal output part, which comprises these amplifiers 2, 3, 4, and 5, constitutes the analog IC. In addition, in the audio signal output device 1, a regulator IC 10, which outputs a predetermined voltage that is lower than the power supply voltage (Vdd), is interposed between the power supply voltage (Vdd) and the analog IC. The important point here is that the regulator 10 is the power supply source of the input stage amplifiers (first input stage amplifier and second input stage amplifier) 2, 4, and the power supply voltage (Vdd) is the power supply source of the output stage amplifiers (first output stage amplifier and second output stage amplifier) 3 and 5.

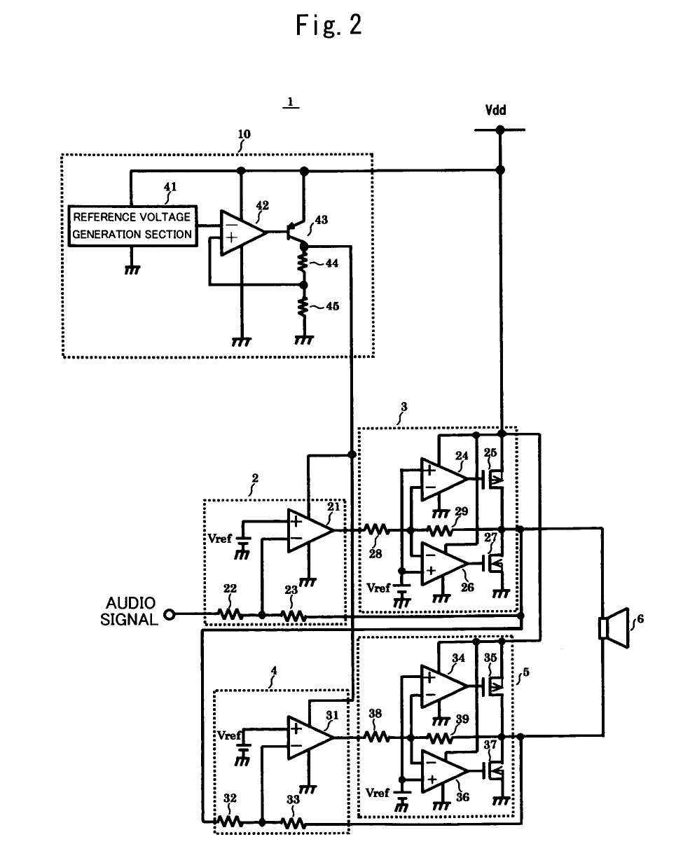

The audio signal output device 1 will be described in more detail by using FIG. 2. The input stage amplifier 2 comprises an input operation amplifier 21, resistors 22 and 23 connected to the inversion input terminal, and a reference voltage Vref connected to the non-inversion input terminal. The audio signal is inputted to the inversion input terminal via the resistor 22, and the inversion input terminal is connected to the output terminal of the output stage amplifier 3 via the resistor 23. The reference voltage Vref may be obtained by dividing the output voltage of the regulator 10 by the resistances.

The input stage amplifier 2 inverts and amplifies the audio signal inputted thereto by means of the input operation amplifier 21, and negative feedback is applied via the resistor 23. Therefore, the overall gain of the audio signal output device 1 is determined by the ratio between the resistances of the resistors 22 and 23, and one terminal of the speaker 6 can be driven in accordance with the audio signal inputted thereto.

The output stage amplifier 3 comprises two output operation amplifiers (first and second output operation amplifiers) 24, 26, a PMOS drive transistor (first transistor) 25 whose gate is connected to the output terminal of the output operation amplifier 24, an NMOS drive transistor (second transistor) 27 whose gate is connected to the output terminal of the output operation amplifier 26, resistors 28 and 29 connected to the inversion input terminals of the output operation amplifiers 24, 26, and a reference voltage Vref connected to the non-inversion input terminals of the output operation amplifiers 24, 26. The output signal of the input stage amplifier 2 is inputted to the respective inversion input terminals of the output operation amplifiers 24, 26 via the resistor 28, and these inversion input terminals are connected to the node between the PMOS drive transistor 25 and the NMOS drive transistor 27, that is, to the output terminal of the output stage amplifier 3, via a resistor 29. As described earlier, the output terminal is connected to the inversion input terminal of the input operation amplifier 21 via the resistor 23. Further, the PMOS drive transistor 25 and NMOS drive transistor 27 are serially connected in this order between the power supply voltage (Vdd) and ground.

The output stage amplifier 3 converts the output signal of the input stage amplifier 2 into a power-supply-side current by means of the output operation amplifier 24 and PMOS drive transistor 25, and into a ground-side current by means of the output operation amplifier 26 and the NMOS drive transistor 27 respectively. Thus, the current driving one terminal of the speaker 6 flows to the PMOS drive transistor 25 or the NMOS drive transistor 27 in accordance with the output signal of the input stage amplifier 2. In other words, the output stage amplifier 3 produces an output by current-amplifying the output of the input stage amplifier 2 inputted thereto to drive one terminal of the drive input of the speaker 6.

The input stage amplifier 4 has the same constitution as the input stage amplifier 2, and comprises an input operation amplifier 31, resistors 32 and 33 connected to the inversion input terminal, and a reference voltage Vref connected to the non-inversion input terminal. The output signal of the output stage amplifier 3 is inputted to the inversion input terminal of the input operation amplifier 31 via the resistor 32, and the inversion input terminal is connected to the output terminal of the output stage amplifier 5 via the resistor 33. With the same resistance values for the resistors 32 and 33, the input stage amplifier 4 inverts the output signal of the output stage amplifier 3 by means of the input operation amplifier 31, negative feedback being applied by means of resistor 33. Here, the input stage amplifier 4 does not amplify the signal inputted.

The output stage amplifier 5 has the same constitution as the output stage amplifier 3, and comprises two output operation amplifiers (third and fourth output operation amplifiers) 34 and 36, a PMOS drive transistor (third transistor) 35 whose gate is connected to the output of the output operation amplifier 34, an NMOS drive transistor (fourth transistor) 37 whose gate is connected to the output of the output operation amplifier 36, resistors 38 and 39 connected to the respective inversion input terminals of the output operation amplifiers 34, 36, and a reference voltage Vref connected to the respective non-inversion input terminals of the output operation amplifiers 34 and 36. The output signal of the input stage amplifier 4 is inputted to the inversion input terminal of the output operation amplifiers 34, 36 via resistor 38, and the inversion input terminals are connected to the node between the PMOS drive transistor 35 and NMOS drive transistor 37 via the resistor 39, that is, to the output terminal of the output stage amplifier 5. As described earlier, the output terminal of the output stage amplifier 5 is connected to the inversion input terminal of the input operation amplifier 31 via the resistor 33. Further, the PMOS drive transistor 35 and NMOS drive transistor 37 are serially connected in this order between the power supply voltage (Vdd) and ground. Similarly to the output stage amplifier 3, in the case of the output stage amplifier 5, the current driving the other terminal of the speaker 6 flows to the PMOS drive transistor 35 or NMOS drive transistor 37 in accordance with the output signal of the input stage amplifier 4. In other words, the output stage amplifier 5 produces an output by current-amplifying the output of the input stage amplifier 4 inputted thereto to drive the other terminal of the drive input of the speaker 6.

The regulator 10 comprises a reference voltage generation section 41, an amplifier 42, to the inversion input terminal of which the output voltage of the reference voltage generation section 41 is inputted, a PNP transistor 43, to the base of which the output of the amplifier 42 is inputted, the emitter of which is connected to the power supply voltage (Vdd), and the collector of which is connected to ground via resistors 44 and 45, wherein the node between the resistors 44 and 45 is connected to the non-inversion input terminal of the amplifier 42. The reference voltage generation section 41 is constituted by a Zener diode, for example, and generates a constant voltage specific to the Zener diode. The regulator 10 is able to obtain a predetermined output voltage that is lower than the power supply voltage (Vdd) from the collector of the PNP transistor 43 by setting the ratio between the resistances of the resistors 44 and 45. Further, the collector of the PNP transistor 43 becomes the output terminal of the regulator 10 which is connected to the power supply of the input operation amplifiers 21, 31 of the first and second input stage amplifiers 2 and 4.

Next, the operation of the audio signal output device 1 will be described. When the power supply voltage (Vdd) is inputted, the regulator 10 operates and the neighboring digital IC such as the DSP and CODEC, which are on the same substrate as the audio signal output device 1, also operate substantially at the same time. These digital IC operate at full swing between the power supply voltage (Vdd) and ground, and hence a loud noise is generated, this noise being superposed on the power supply voltage (Vdd). However, the first and second input stage amplifiers 2 and 4 are able to receive a stabilized supply of power from the regulator 10 regardless of the noise from the digital IC. Therefore, the audio signal is inverted and amplified by means of the input stage amplifier 2 without undergoing the effects of noise. The output of the output stage amplifier 3 is inverted by the input stage amplifier 4 without being subject to the effects of noise.

Here, the power supply voltage (Vdd), which is subject to the effects of noise from the digital IC, constitutes the power supply source of the output stage amplifiers 3 and 5. However, the output signals of the input stage amplifiers 2 and 4 inputted to the output stage amplifiers 3 and 5 are not subject to the effects of noise and the output stage amplifiers 3 and 5 have a BTL constitution. The output stage amplifiers 3 and 5 operate with substantially the same timing, and common mode noise is cancelled out, meaning that the effect of this noise is negligible. In addition, the regulator 10 does not supply power for the output stage amplifiers 3 and 5 that consume a large amount of electricity. Hence, a small current capacity, more specifically of about 200 to 300 μA, is adequate. Therefore, the heat radiated by the regulator 10 is small and a heat sink need not be provided. Thus, the area of the substrate occupied by the regulator 10 is small and package costs can be kept low in comparison with those of the prior art.

Further, although the regulator 10 may be provided separately from the analog IC, because the current capacity may be small, the regulator 10 may be formed on the same integrated circuit as the analog IC, whereby further cost reductions can be achieved.

Moreover, the present invention is not limited to the above embodiment. A variety of design modifications are possible within the scope of the items appearing in the claims.

1. An audio signal output device, comprising:
a first input stage amplifier that produces an output by inverting and amplifying an audio signal inputted thereto;
a first output stage amplifier that produces an output by current-amplifying the output signal of the first input stage amplifier inputted thereto to drive one terminal of the drive input of a speaker;
a second input stage amplifier that produces an output by inverting the output signal of the first output stage amplifier inputted thereto;
a second output stage amplifier that produces an output by current-amplifying the output signal of the second input stage amplifier inputted thereto to drive the other terminal of the drive input of the speaker; and
a regulator that is connected to the power supply voltage and outputs a predetermined constant voltage that is lower than the power supply voltage,
wherein the first and second input stage amplifiers employ the regulator as a power supply source and the first and second output stage amplifiers employ the power supply voltage as the power supply source.

2. The audio signal output device according to claim 1, wherein
the first output stage amplifier comprises first and second output operation amplifiers, to the inversion input terminal of which the output signal of the first input stage amplifier is inputted via a resistor; a first transistor to which the output signal of the first output operation amplifier is inputted; and a second transistor to which the output signal of the second output operation amplifier is inputted,
wherein the first and second transistors are serially connected between the power supply voltage and ground, and the node between the first and second transistors is connected to the inversion input terminals of the first and second output operation amplifiers via a resistor and becomes the output of the first output stage amplifier; and
the second output stage amplifier comprises third and fourth output operation amplifiers, to the inversion input terminal of which the output signal of the second input stage amplifier is inputted via a resistor; a third transistor to which the output signal of the third output operation amplifier is inputted; and a fourth transistor to which the output signal of the fourth output operation amplifier is inputted,
wherein the third and fourth transistors are serially connected between the power supply voltage and ground, and the node between the third and fourth transistors is connected to the inversion input terminals of the third and fourth output operation amplifiers via a resistor and becomes the output of the second output stage amplifier.

3. The audio signal output device according to claim 1, wherein the regulator comprises:
a reference voltage generation section;
an amplifier to the inversion input terminal of which the output signal of the reference voltage generation section is inputted; and
a PNP transistor to the base of which the output signal of the amplifier is inputted, the emitter of which is connected to the power supply voltage, and the collector of which is connected to ground via two resistors,
and wherein the node between the two resistors is connected to the non-inversion input terminal of the amplifier, and the collector of the PNP transistor is the output terminal of the regulator.

4. The audio signal output device according to claim 2, wherein the regulator comprises:
a reference voltage generation section;
an amplifier to the inversion input terminal of which the output signal of the reference voltage generation section is inputted; and
a PNP transistor to the base of which the output signal of the amplifier is inputted, the emitter of which is connected to the power supply voltage, and the collector of which is connected to ground via two resistors,
and wherein the node between the two resistors is connected to the non-inversion input terminal of the amplifier, and the collector of the PNP transistor is the output terminal of the regulator.
